(19) United States
(12) Patent Application Publication
(10) Pub. No.: US 2024/0191393 A1
(43) Pub. Date: Jun. 13, 2024

(54) EPITAXY SUSCEPTOR, EPITAXY GROWTH APPARATUS AND MANUFACTURING METHOD OF SEMICONDUCTOR DEVICE

(71) Applicant: Zing Semiconductor Corporation, Shanghai (CN)

(72) Inventors: Gongbai CAO, Shanghai (CN); Shuai PAN, Shanghai (CN)

(73) Assignee: Zing Semiconductor Corporation, Shanghai (CN)

(21) Appl. No.: 18/532,964

(22) Filed: Dec. 7, 2023

(30) Foreign Application Priority Data
Dec. 12, 2022 (CN) 202211597733.9

(51) Int. Cl. C30B 25/12; H01L 21/02

(52) U.S. Cl. CPC C30B 25/12; H01L 21/02532

(57) ABSTRACT

The present application provides an epitaxy susceptor, an epitaxy growth apparatus and a manufacturing method of semiconductor device. The epitaxy susceptor comprises a pocket, wherein the pocket comprises plural lift-pin holes for setting lift-pins, and each lift-pin hole is surrounded by at least one auxiliary through hole penetrating the pocket. By setting plural auxiliary through holes with various diameters and/or various distributions surrounding the lift-pin holes in the pocket of the epitaxy susceptor, the physical properties near the lift-pin hole can be similar with that of auxiliary through holes, such that the abnormal thickness of the epitaxial film of the wafer at the site corresponding the lift-pin hole can be eliminated or reduced.

### BACKGROUND OF THE INVENTION

### 1. Field of the Invention

The present invention relates to a technical field of semiconductor, and more particularly to an epitaxy susceptor, an epitaxy growth apparatus and a manufacturing method of a semiconductor device.

### 2. Description of the Related Art

Silicon epitaxy growth is an important process in semiconductor manufacture. Epitaxy process includes vacuum epitaxy, vapor phase epitaxy (VPE), liquid phase epitaxy and the like, in which silicon VPE has the broadest applications. The mechanism of VPE is that, under high temperature, a silicon source having strong volatility such as trichlorosilane (TCS) reacts with hydrogen or is pyrolyzed to form silicon atoms, and the silicon atoms deposit on a wafer to form an epitaxial layer.

Uniformity of the epitaxial layer in thickness and resistivity is critical parameters for performance of the semiconductor device. While the uniformity of the epitaxial layer is improved, the yield and the performance of the semiconductor device are better. During the epitaxy growth process, the uniformity of the epitaxial layer in thickness and resistivity can be optimized within a certain range by adjusting process parameters such as gas flow, power, temperature distribution and the like. However, some distribution characteristics of thickness and resistivity of the epitaxial layer are restricted by the hardware, for example, direction of the gas flow, proportion and distribution of the gas flow, arrangement of inlet and outlet of the gas and the like, causing certain fixed distribution characteristics.

During the epitaxy growth process of a wafer or other high temperature epitaxy growth processes, a wafer is placed on a susceptor and subjected to a heating step, an epitaxy step and a cooling step. At the step of placing the wafer to the susceptor or the step of removing the wafer from the susceptor, a lift-pin is applied to move the wafer to or from the susceptor via a lift-pin hole, but the lift-pin holes in the susceptor results in temperature distribution change in the local areas of the wafer, causing abnormal thickness of the epitaxial layer within the local area. Such abnormal film thickness of the wafer at the site corresponding to the lift-pin hole shows color difference, i.e. imprinting, causing abnormal appearance and abnormal electrical properties of the wafer.

Conventionally, the imprinting problem is alleviated by adjusting temperature distribution or power distribution to the susceptor and the wafer surface, but the range of temperature or power for the adjustment is restricted because temperature and power significantly correspond to the deposition rate and the thickness distribution of the epitaxial layer. It is difficult to balance the above factors.

### SUMMARY

The purpose of the present application is to provide an epitaxy susceptor, an epitaxy growth apparatus and a manufacturing method of a semiconductor device to solve the problem of abnormal thickness of the epitaxial layer within the local area that the lift-pin hole locates.

To solve the problems in the conventional technologies, the present application provides an epitaxy susceptor comprising: a pocket, wherein the pocket comprises plural lift-pin holes for setting lift-pins, and each lift-pin hole is surrounded by at least one auxiliary through hole penetrating the pocket.

In another aspect, the present application provides an epitaxy growth apparatus comprising any of the epitaxy susceptors as described above.

In another aspect, the present application provides a manufacturing method of a semiconductor device comprising growing an epitaxy layer on a wafer by applying the epitaxy growth apparatus as described above.

### BRIEF DESCRIPTION OF THE DRAWINGS

FIG. 1 shows the structure of the pocket of the susceptor in one embodiment of the present application.

FIG. 2 shows the distribution of the lift-pin holes and the auxiliary through holes in one embodiment of the present application.

FIG. 3 shows the distribution of the lift-pin holes and the auxiliary through holes in another embodiment of the present application.

FIG. 4 shows the thickness of the epitaxy layer on the backside of the wafer near the lift-pin hole in one embodiment of the present application.

### DETAILED DESCRIPTION OF THE EMBODIMENTS

The present application provides an epitaxy susceptor comprising: a pocket, wherein the pocket comprises plural lift-pin holes for setting lift-pins, and each lift-pin hole is surrounded by at least one auxiliary through hole penetrating the pocket.

In one embodiment, each of the lift-pin holes is surrounded by plural auxiliary through holes. The plural auxiliary through holes are distributed with a gradually decreased density outward from the lifting pin hole.

In one embodiment, each of the lift-pin holes is surrounded by plural auxiliary through holes, and the auxiliary through holes are evenly distributed around the lift-pin hole.

In one embodiment, the auxiliary through holes distributed around the lifting pin hole as a shape such as triangle, quadrangle, honeycomb hexagon, close-packed

In one embodiment, the auxiliary through holes are distributed in an area of 6 mm-15 mm from a center of the lift-pin hole.

In one embodiment, the auxiliary through hole is circular.

In one embodiment, the auxiliary through hole has a diameter of 0.5 mm-2 mm.

In one embodiment, the auxiliary through hole has a space distance of 1 mm-6 mm with an adjacent auxiliary through hole.

The present application also provides an epitaxy growth apparatus comprising any of the epitaxy susceptors as described above.

The present application further provides a manufacturing method of a semiconductor device comprising growing an epitaxy layer on a wafer by applying the epitaxy growth apparatus as described above.

In the present application, by setting at least one auxiliary through hole penetrating the pocket surrounding the lift-pin hole, the physical properties of the wafer near the lift-pin hole are similar with that near the auxiliary through hole, such that the abnormal thickness of the epitaxy film near the site that the lift-pin hole locates can be reduced or eliminated.

### Examples

Example embodiments will now be described more fully with reference to the accompanying drawings. Noted that accompanying drawing is simplified and applies non-accurately ratio for the purpose of clear and convenient illustration of the example of the present invention.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

The inventor found that, during the epitaxy growth process of a wafer, the epitaxial layer of the wafer shows color difference i.e. imprinting, at the site corresponding to the lift-pin hole. Namely, the thickness of the epitaxial layer of the wafer at the site corresponding to the lift-pin hole is abnormal, causing abnormal electrical properties of the wafer. Since the temperature distribution of the pocket is uneven because of the lift-pin hole and the deposition gas passes through the lift-pin hole to the backside of the wafer, the epitaxial layer has abnormal thickness at the site corresponding to the lift-pin hole. In particular, on the backside of the wafer, the epitaxial layer has a relative high thickness at the site corresponding to the center of the lift-pin hole, but has a relative low thickness at the site corresponding to the area of the pocket surrounding the lift-pin hole. On the topside of the wafer, the epitaxial layer is thinner at the site corresponding to the center of the lift-pin hole because of lower temperature. It is difficult to improve the quality of film thickness by adjustment of temperature.

Accordingly, the present application provides embodiments of an epitaxy susceptor, an epitaxy growth apparatus and a manufacturing method of a semiconductor device. By setting at least one auxiliary through hole penetrating the pocket surrounding the lift-pin hole, the physical properties of the wafer near the lift-pin hole are similar with that near the auxiliary through hole, such that the abnormal thickness of the epitaxy film near the site that the lift-pin hole locates can be reduced or eliminated.

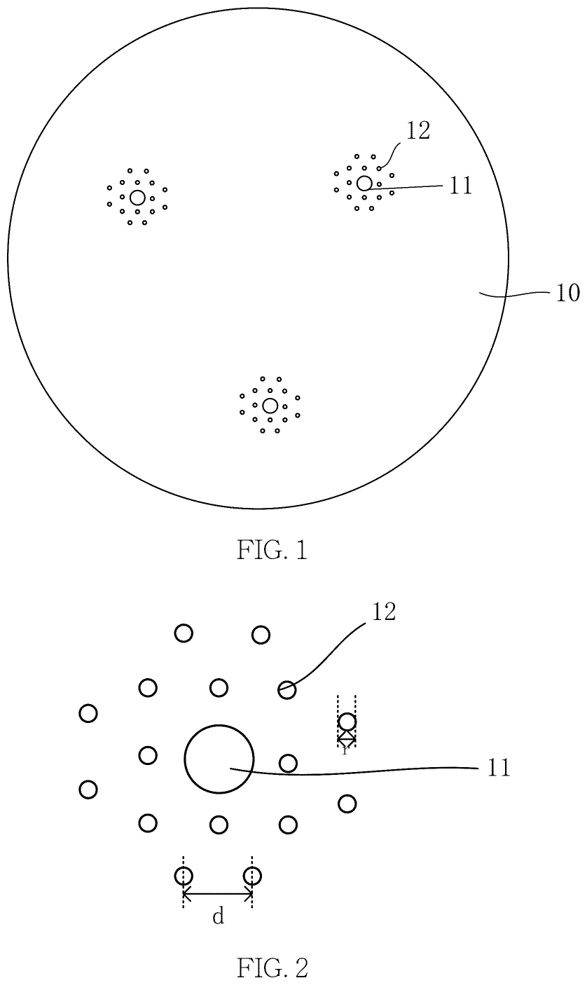

FIG. 1 shows the structure of the pocket of the susceptor in one embodiment of the present application. As shown in FIG. 1, this example provides a susceptor comprising a pocket 10. There are plural lift-pin holes 11 setting in the pocket 10. The lift-pin hole 11 penetrates through the pocket 10 and accommodates the lift-pin. The lift-pin is located in the lift-pin hole 11, and moves along with the penetration direction, i.e. the thickness direction of the pocket 10, to support the wafer on the pocket, such that the wafer can be lifted from or laid down to the pocket. Each lift-pin hole 11 is surrounded by at least one auxiliary through hole 12 penetrating the pocket 10.

FIG. 2 shows the distribution of the lift-pin holes and the auxiliary through holes in one embodiment of the present application. The susceptor comprises a pocket and a sidewall (not shown) on periphery of the susceptor. As shown in FIG. 2, three lift-pin holes 11 are set in the pocket 10 and construct an equilateral triangle. Each of the lift-pin holes 11 are surrounded by plural auxiliary through holes 12 with an even distribution. The distribution of the plural auxiliary through holes 12 can be a shape such as triangle, quadrangle, honeycomb hexagon, close-packed hexagonal shape and the like. In one preferred embodiment, the auxiliary through holes 12 are located in an area of 6 mm-15 mm from a center of the lift-pin hole. The inventor founds that the epitaxy thickness of the wafer has violent fluctuations in this area, such that the auxiliary through holes 12 setting within this area are able to provide more improvements. The shape of the auxiliary through hole 12 may be such as circular. The diameter r of the auxiliary through hole 12 may be such as 0.5 mm-2 mm. The space distance d between two adjacent auxiliary through holes 12 may be such as 1 mm-6 mm. The shape of the lift-pin hole 11 is circular. The diameter of the lift-pin hole 11 is 4 mm. The diameter of the auxiliary through hole 12 should be smaller than that of the lift-pin hole 11, such that the fluctuations of thickness of the epitaxial layer caused by the lift-pin hole 11 can be alleviated or reduced gradually.

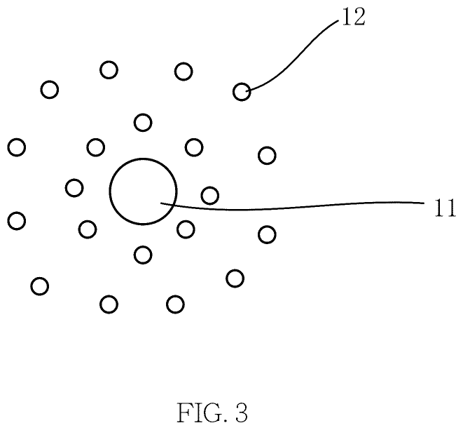

FIG. 3 shows the distribution of the lift-pin holes and the auxiliary through holes in another embodiment of the present application. As shown in FIG. 3, each of the lift-pin holes 11 is surrounded by the plural auxiliary through holes 12, and the plural auxiliary through holes 12 are distributed with a gradually decreased density outward from the lifting pin hole 11, such that affections of the lifting pin hole in wafer temperature and the amount of flow of the deposition gas can be reduced gradually. In one example, as shown in FIG. 3, each of the lift-pin holes 11 is surrounded by two circles of the auxiliary through holes 12, i.e. the inner circle and the outer circle. In one lift-pin hole 11 and its surrounding auxiliary through holes 12, the space distance between two adjacent auxiliary through holes 12 in the inner circle is smaller than that in outer circle, and the space distance between the lift-pin hole 11 and the auxiliary through hole 12 in the inner circle is smaller than that between the auxiliary through holes 12 in the inner circle and in the outer circle. In one embodiment, the inner circle has eight auxiliary through holes 12 and the outer circle has twelve auxiliary through hole 12. It should be understood that the number of the auxiliary through holes is not restricted and can be adjusted depending on situation.

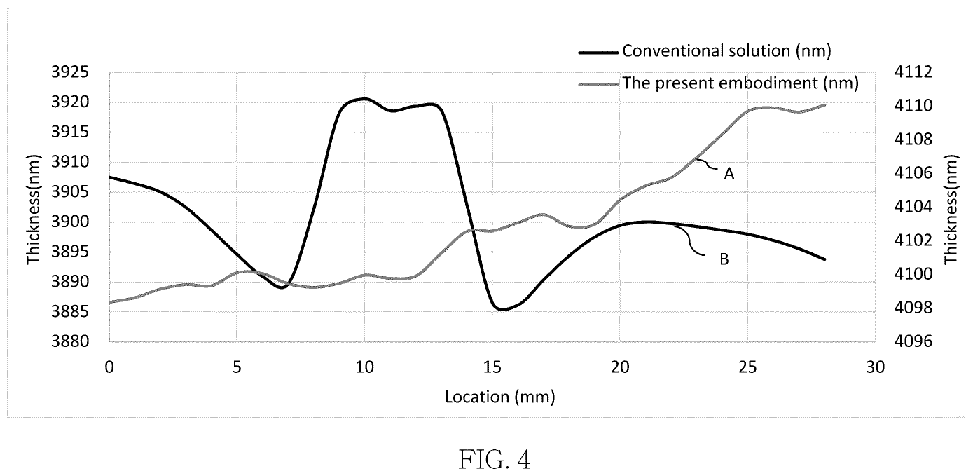

The lift-pin hole significantly affects the epitaxial layer on the backside of the wafer because of the factors including temperature and gas flow. This example proves the advantages of the arrangement of lift-pin hole and auxiliary through holes for the epitaxy layer on backside of wafer according to one embodiment of the present application. FIG. 4 shows the thickness change of the epitaxy layer on the backside of the wafer near the lift-pin hole and compares the solution of the present application (curve A) and the conventional technology (curve B). As shown in FIG. 4, X-axis is the location on the wafer, Y-axis is the thickness of the epitaxy layer on the backside of the wafer.

Observing the thickness change in the conventional technology, i.e. curve B in FIG. 4, the location on the wafer corresponding to the lift-pin hole 11 is between 6 mm-15 mm, and the thickness of the epitaxial layer within this area has about 31 nm of a difference between the maximum and the minimum of epitaxial layer thickness. Such dramatic thickness change is caused by the lift-pin hole 11, i.e. a hole penetrating the pocket. During the epitaxy growth process of a wafer, the temperature of the growth chamber maintains at 1000° C.-1200° ° C. The higher temperature results in the higher deposition rate of the epitaxial layer. However, the temperature of the pocket at the site around the lift-pin hole is decreased because the gas flows through the lift-pin hole, such that the closer to the lifting pin hole 11, the thinner the epitaxial layer becomes. On the other hand, the flow amount of the deposition gas also significantly affects the thickness of the epitaxial layer, namely, the larger flow amount of the deposition gas results in the thicker epitaxial layer. Since the deposition gas passes through the lift-pin hole 11 to the backside of the wafer, the epitaxial layer on the site corresponding to the lift-pin hole 11 has an increased thickness. Such thickness difference on the backside of the wafer around the lift-pin hole 11 shows color difference, i.e. imprinting.

Observing the curve A in FIG. 4, the location on the wafer corresponding to the lift-pin hole 11 is between 6 mm-15 mm, and the thickness of the epitaxial layer on the backside of the wafer is slowly increased within this area. The thickness of the epitaxial layer within this area has about 2 nm of a difference between the maximum and the minimum of epitaxial layer thickness. Obviously, by setting at least one auxiliary through hole 12 penetrating the pocket and surrounding the lift-pin hole 11, the physical properties of the area around the lift-pin hole 11 can be similar to that around the auxiliary through hole 12, causing slow and gentle changes of the pocket temperature and the gas flow around the lift-pin hole 11. Thereby, the thickness of the epitaxial layer on the backside of the wafer around the lift-pin hole 11 changes gently and gradually, and the color difference, i.e. imprinting, of the epitaxial layer of the wafer can be eliminated.

By applying the present application, the epitaxial layer on the topside of the wafer can be improved. The conventional arrangement of the lift-pin hole 11 makes the temperature at the corresponding site of the wafer decrease, causing the reduced growth rate of the epitaxial layer. Therefore, while the conventional arrangement of the lift-pin hole 11 is applied, the epitaxial layer on the topside of the wafer at the site corresponding to the lift-pin hole 11 becomes thinner. On the contrary, at least one auxiliary through hole 12 penetrating the pocket is distributed around the lift-pin hole 11 in the example of the present application, such that the physical properties of the area around the lift-pin hole 11 can be close to that around the auxiliary through hole 12. For example, the temperature of the pocket has slow and gentle changes at the site corresponding to the lift-pin hole 11, thereby the thickness of the epitaxial layer on the topside of the wafer around the lift-pin hole 11 changes gently and gradually, and the problems of thickness change of the epitaxial layer on the topside of the wafer can be solved.

The susceptor comprises a pocket 10 and a sidewall (not shown in the figures) on periphery of the susceptor. The sidewall and the pocket combine to form a bearing tank. In particular, the sidewall is applied to optimize the horizontal gas flow field of process gases during the epitaxy growth process. In one embodiment, an outlet of the process gas can be set in the inner wall of the sidewall to further optimize the gas flow field.

The present application provides an embodiment of an epitaxy growth apparatus comprising a chamber and an epitaxy susceptor as described above. The epitaxy susceptor is set in the chamber. An inlet and an outlet for feeding and exhausting the reaction gases are provided on the side of the chamber. The outer periphery of the lower surface of the susceptor is fitted and supported by a susceptor supporting shaft connected to a rotating portion of the susceptor, and simultaneously rotates with the susceptor supporting shaft. The base end of the lift-pin is supported and lifted by a lifting shaft.

The present application further provides an embodiment of a manufacturing method of a semiconductor device comprising: growing an epitaxy layer on a wafer by applying an epitaxy growth apparatus as described above. In the manufacturing method, the process temperature is such as 1000° C.-1100° ° C. In one embodiment, the deposition gas can be, for example, silanes, dichlorosilane, trichlorosilane or any combination thereof. In one embodiment, the gas flow amount of the deposition gas applied in the manufacturing method can be, for example, 70 standard liter per minute (slm)-100 slm. In one embodiment, the deposition gas can be fed into the chamber with a carrier gas, and the carrier gas can be, for example, nitrogen (N₂), hydrogen (H₂), argon (Ar), helium (He) or any combination thereof. In one embodiment, the gas flow of the carrier gas can be, for example, 60 slm-70 slm.

According to the above, in the epitaxy susceptor, the epitaxy growth apparatus and the manufacturing method of a semiconductor device of the present application, by setting at least one auxiliary through hole penetrating the pocket and surrounding the lift-pin hole of the pocket of the susceptor, the physical properties of the area around the lift-pin hole can be similar to that around the auxiliary through hole, thereby the abnormal thickness of the epitaxial layer at the site corresponding to the lift-pin hole can be reduced or eliminated.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. An epitaxy susceptor comprising: a pocket, wherein the pocket comprises plural lift-pin holes for setting lift-pins, and each lift-pin hole is surrounded by at least one auxiliary through hole penetrating the pocket.

2. The epitaxy susceptor of claim 1, wherein each lift-pin hole is surrounded by plural auxiliary through holes, and the plural auxiliary through holes are distributed with a gradually decreased density outward from the lifting pin hole.

3. The epitaxy susceptor of claim 1, wherein each lift-pin hole is surrounded by plural auxiliary through holes, and the auxiliary through holes are evenly distributed around the lift-pin hole.

4. The epitaxy susceptor of claim 3, wherein the auxiliary through holes distributed around the lifting pin hole as a shape selected from a triangle, a quadrangle, a honeycomb hexagon, or a close-packed hexagonal shape.

5. The epitaxy susceptor of claim 1, wherein the auxiliary through holes are distributed in an area of 6 mm-15 mm from a center of the lift-pin hole.

6. The epitaxy susceptor of claim 1, wherein the auxiliary through hole is circular.

7. The epitaxy susceptor of claim 6, wherein the auxiliary through hole has a diameter of 0.5 mm-2 mm.

8. The epitaxy susceptor of any of claim 1, wherein the auxiliary through hole has a space distance of 1 mm-6 mm with an adjacent auxiliary through hole.

9. An epitaxy growth apparatus comprising an epitaxy susceptor of claim 1.

10. A manufacturing method of a semiconductor device comprising: growing an epitaxy layer on a wafer by applying an epitaxy growth apparatus of claim 9.
